(19) United States
(12) Patent Application Publication
(10) Pub. No.: US 2024/0312821 A1
(43) Pub. Date: Sep. 19, 2024

(54) AUTOMATIC TEACHING APPARATUS FOR SEMICONDUCTOR MANUFACTURING EQUIPMENT

(71) Applicant: KABUSHIKI KAISHA YASKAWA DENKI, Fukuoka (JP)

(72) Inventors: Jung-ho YUN, Gyeonggi-do (KR); Yonggu KANG, Gyeonggi-do (KR); Mid Uem RYU, Gyeonggi-do (KR); Hiroki SANEMASA, Fukuoka (JP); Takashi MINAMI, Fukuoka (JP); Daisuke HIGASHITARUMIZU, Fukuoka (JP)

(21) Appl. No.: 18/670,921

(22) Filed: May 22, 2024

Related U.S. Application Data
(63) Continuation of application No. PCT/KR2022/013064, filed on Aug. 31, 2022.

(30) Foreign Application Priority Data
Nov. 23, 2021 (KR) 10-2021-0162099

(51) Int. Cl. H01L 21/68; B25J 9/16; B65G 47/90; H01L 21/687

(52) U.S. Cl. CPC H01L 21/681; B25J 9/163; B65G 47/905; H01L 21/68707

(57) ABSTRACT

An automatic teaching apparatus for semiconductor manufacturing equipment includes: an equipment front end module (EFEM); one or more load ports provided along an edge of one side of the EFEM to be connected to an inside of the EFEM; a transfer robot disposed in the inside of the EFEM and configured to transfer a wafer to the one or more load ports by an end effector to process the wafer, and a load port teaching unit configured to detect a fixed position of the end effector in a state of unloading the wafer such that the wafer is placed in the fixed position within the load port.

### CROSS-REFERENCE TO RELATED APPLICATIONS

This application is a continuation application of International Patent Application No. PCT/KR2022/013064, filed on Aug. 31, 2022, which claims priority to Korean Patent Application No. 10-2021-0162099, filed on Nov. 23, 2021, with the Korean Intellectual Property Office (KIPO), all of which are incorporated herein in their entireties by reference.

### TECHNICAL FIELD

The present disclosure relates to an automatic teaching apparatus for semiconductor manufacturing equipment.

### BACKGROUND

Semiconductor devices are manufactured by a number of processes such as a thin film deposition process, an ion implantation process, a diffusion process, a cleaning process, a photolithography process, and an etching process. As for an apparatus where such semiconductor manufacturing processes are carried out, a single-wafer processing apparatus is being widely used to process wafers one by one.

For example, in the cleaning process, single-wafer cleaning for treating wafers with chemicals to remove contamination such as particles, metal impurities, and organic materials and cleaning the wafers one by one is being widely used in order to satisfy high cleanliness. It is common for a single-wafer cleaning device to have a buffer where wafers are held in a stand-by state in order to ensure a smooth supply of the wafers between a loading section where the wafers are loaded and a cleaning section where the cleaning process is performed.

When the wafers are loaded into the buffer by a transfer robot, if the transfer robot is misaligned, the wafers are placed in wafer slots of the buffer in misaligned positions.

If the positions of the wafers in the buffer are misaligned, when the wafers are transferred to the cleaning section, there may occur problems in which the wafers deviate from the transfer robot, resulting in damage to the wafers, or the wafers are not placed correctly in the cleaning section, causing a cleaning operation to stop.

In addition, even if the wafer does not deviate from the transfer robot, when the misalignment of a wafer position is detected by a wafer position detection sensor, the progress of the process needs to be stopped to shut down manufacturing equipment and the degree of misalignment of the transfer robot needs to be measured to conduct an operation of teaching the transfer robot manually.

It takes a substantial time to shut down the manufacturing equipment and teach the transfer robot, which reduces the productivity of the process. In addition, since an operator enters into a clean space inside an equipment front end module (EFEM) and manually installs jigs and teaches the transfer robot in a state where the EFEM is opened to the atmosphere, there are problems in which the inside of the EFEM is contaminated due to foreign materials brought in from the outside of the EFEM. This leads to a decrease in cleanliness of the entire manufacturing equipment, and a process of cleaning the inside of the EFEM is repeated to restore the decreased cleanliness to a desired level, thereby prolonging the overall work time.

In addition, in the EFEM, which is capable of mounting five wafer carriers (e.g., front opening unified pods (FOUPs)), there may be cases where unlike three centrally positioned wafer carriers that allow the hand of the transfer robot to access an opening of the wafer carrier almost in a straight line, for two wafer carriers positioned on both ends of the five wafer carriers, the hand of the transfer robot has to approach the two wafer carriers slantingly to deliver a wafer depending on a range where the transfer robot's hand may reach. At this time, there are some cases where the hand of the robot interferes with surrounding portions, in particular, a side wall of the wafer carrier, making safe teaching operations difficult.

Therefore, there is a need to solve these problems.

The related art has been proposed in Korean Patent Publication No. 10-2013-0058413 (Publication Date: Jun. 4, 2013, Title of Invention: Substrate Processing Apparatus).

The above-described technical configuration is the background art to aid understanding of the present disclosure and does not mean widely known prior arts in the technical field to which the present disclosure belongs.

### SUMMARY

Embodiments disclosed herein were designed to overcome the above-mentioned problems. An object of the embodiments is to provide an automatic teaching apparatus for semiconductor manufacturing equipment, which aims to reduce the teaching time compared to a process of performing a teaching operation of an end effector or wafer on an existing teaching jig that is manually installed, by setting the end effort in a fixed position in a Y-direction and a Z-direction using a front end sensor provided on the end effector of the transfer robot and then, setting the end effort in a fixed position in an X-direction and a Z-direction using a central sensor of a center hole portion formed in the end effector to complete a teaching process of the wafer, through detection pins and semicircular blocks of load ports and stations provided along edges of an equipment front end module (EFEM) for a wafer processing process, without using a separate teaching jig that is manually installed.

Also, an object of the disclosed embodiments is to provide a teaching jig capable of being mounted on a load port, similarly to a wafer carrier (e.g., a front opening unified pod (FOUP)) capable of accommodating wafers therein, so that a teaching process for a transfer robot may be automatically performed while a clean space of the EFEM is maintained without an operator entering into the EFEM in a state where the EFEM is opened to the atmosphere.

Furthermore, an object of the disclosed embodiments is to provide a teaching system and a teaching jig, capable of accurately teaching a delivery position of a wafer safely without a hand of a transfer robot being interfered with the surroundings thereof (in particular, a side wall of the wafer carrier) even when the hand of the transfer robot needs to access the wafer in the wafer carrier slantingly.

An automatic teaching apparatus for semiconductor manufacturing equipment according to an embodiment disclosed herein includes an equipment front end module (EFEM); one or more load ports provided along an edge of one side of the EFEM to be connected to an inside of the EFEM; a transfer robot disposed in the inside of the EFEM and configured to transfer wafers to the one or more load ports by an end effector to process the wafers; a load port teaching unit configured to detect a fixed position of the end effector in a state of unloading the wafer such that the wafer is placed in the fixed position within the load port; one or more stations provided along an edge of another side of the EFEM to be connected to the inside of the EFEM; and a station teaching unit configured to detect a fixed position of the end effector in a state of unloading the wafer such that the wafer is placed in the fixed position within the station.

The end effector includes a base pad having at least a top surface formed in a planar shape; and two forks extending to a front side of the base pad.

As one example, the load port teaching unit includes: a detection pin protruding from an inner bottom surface of a specific load port, a dummy port, or the EFEM to correspond to a front edge or a center of the wafer in plane; a semicircular block protruding from the inner bottom surface of the specific load port, the dummy port, or the EFEM at a position spaced apart by a set distance along a straight line with the detection pin in an entry direction of the end effector; a front end sensor provided on each of the forks in a straight line to face each other and configured to detect and guide an entry position of the end effector in a Y-direction and a Z-direction such that the detection pin is positioned at a center between the forks in plane and a set height; a central hole portion penetrating through the base pad such that the detection pin is positioned therein when the forks move forward and the front end sensor detects the semicircular block; and one or more central sensors provided on the base pad along an edge of the central hole portion to interact with the central hole portion in an inward direction and set a position of the end effector in an X-direction and a Z-direction such that the detection pin is set at the set position.

As another example, the load port teaching unit includes: a base plate placed at a set position on an inner bottom of a specific load port, a dummy port, or the EFEM; a detection pin protruding from a bottom surface of the base plate to correspond to a front edge or a center of the wafer in plane; a semicircular block protruding from the base plate at a position spaced apart by a set distance along a straight line with the detection pin in an entry direction of the end effector; a front end sensor provided on each of the forks in a straight line to face each other and configured to detect and guide an entry position of the end effector in a Y-direction and a Z-direction such that the detection pin is positioned at a center between the forks in plane and a set height; a central hole portion penetrating through the base pad such that the detection pin is positioned therein when the forks move forward and the front end sensor detects the semicircular block; and one or more central sensors provided on the base pad along an edge of the central hole portion to interact with the central hole portion in an inward direction and set a position of the end effector in an X-direction and a Z-direction such that the detection pin is set at the set position.

When the dummy port is positioned inside the specific load port, the dummy port is set at a fixed position with respect to the load port by a first positioner.

As another example, there is provided a transfer apparatus including a teaching system for teaching a delivery position of a wafer in a wafer carrier (e.g., a front opening unified pod (FOUP)) disposed on a load port installed in the transfer apparatus that forms a clean space, the transfer apparatus comprising: a robot including a hand configured to hold a wafer, an arm configured to move the hand in a horizontal direction and a vertical direction, and a sensor provided on the hand; a robot control device configured to perform at least detection of the sensor, and movement control of the arm and the hand; and a teaching jig disposed on the load port and configured to maintain the clean space of the transfer apparatus in the same position as the delivery position of a wafer in the wafer carrier by the robot, in which the teaching jig has a specific feature disposed to determine a relative positional relationship with the delivery position of the wafer in the wafer carrier, and the robot control device operates the hand to detect the specific feature of the teaching jig by the sensor and stores the delivery position of the wafer based on a detected position of the specific feature.

As another example, there is provided a teaching system for teaching a delivery position of a wafer in a wafer carrier (e.g., a front opening unified pod (FOUP)) disposed on a load port installed in a transfer apparatus that forms a clean space, the teaching system comprising: a robot including a hand configured to hold a wafer, an arm configured to move the hand in a horizontal direction and a vertical direction, and a sensor provided on the hand; a robot control device configured to perform at least detection of the sensor, and movement control of the arm and the hand; and a teaching jig disposed on the load port and configured to maintain the clean space of the transfer apparatus in the same position as the delivery position of the wafer in the wafer carrier by the robot, in which the teaching jig has a specific feature disposed to determine a relative positional relationship with the delivery position of the wafer in the wafer carrier, and the robot control device operates the hand to detect the specific feature of the teaching jig by the sensor and stores the delivery position of the wafer based on a detected position of the specific feature.

As another example, there is provided a teaching jig for teaching a robot a delivery position of a wafer within a wafer carrier (e.g., a front opening unified pod (FOUP)) disposed on a load port installed in a transfer apparatus that forms a clean space, the teaching jig comprising: a housing disposed in the load port, configured to maintain the clean space of the transfer apparatus in the same position as the delivery position of the wafer in the wafer carrier by the robot, and having an opening in one surface thereof, in which an interior of the housing is provided with a specific feature disposed to determine a relative positional relationship with the delivery position of the wafer in the wafer carrier.

As another example, there is provided a robot that performs delivery of a wafer to and from a wafer carrier (e.g., a front opening unified pod (FOUP)) disposed on a load port installed in a transfer apparatus that forms a clean space, the robot comprising: a hand configured to hold the wafer; an arm configured to move the hand in a horizontal direction and a vertical direction; and a sensor provided on the hand, in which the robot detects a teaching jig for teaching a delivery position of the wafer in the wafer carrier by the sensor, thereby teaching the delivery position of the wafer, the teaching jig is disposed in the load port, configured to maintain the clean space of the transfer apparatus in the same position as the delivery position of the wafer in the wafer carrier by the robot, and has a specific feature disposed to determine a relative positional relationship with the delivery position of the wafer in the wafer carrier, and the robot operates the hand to detect the specific feature of the teaching jig by the sensor, and teaches the delivery position of the wafer based on a detected position of the specific feature.

As described above, the automatic teaching apparatus for semiconductor manufacturing equipment according to the embodiment of the present disclosure may reduce the teaching time compared to a process of performing a teaching operation of an end effector or wafer on an existing teaching jig that is manually installed, by setting the end effort in a fixed position in a Y-direction and a Z-direction using a front end sensor provided on the end effector of the transfer robot and then, setting the end effort in a fixed position in an X-direction and a Z-direction using a central sensor of a center hole portion formed in the end effector to complete a teaching process of the wafer, through detection pins and semicircular blocks of load ports and stations provided along edges of an equipment front end module (EFEM) for a wafer processing process, without using a separate teaching jig that is manually installed unlike the prior art.

In addition, the teaching system according to the embodiment of the present disclosure may perform a teaching operation for the transfer robot while maintaining a clean space of the EFEM, without an operator entering into the EFEM.

In particular, even when the hand of the transfer robot needs to access the wafer slantingly, the hand of the transfer robot may safely and accurately teach the delivery position of the wafer without being interfered with the surroundings thereof (in particular, a side wall of the wafer carrier).

Furthermore, since the teaching jig may be installed in the load port of the EFEM where the wafer carrier is mounted without an operator entering into the EFEM, it is possible to confirm a teaching position of the robot regularly and automatically while maintaining a clean space of the EFEM and acquire the teaching position regularly to perform teaching again if the teaching position deviates from a predetermined standard. Also, by regularly acquiring the teaching position and accumulating this data, teaching may be performed at appropriate times.

The above summary is for illustrative purposes only and is not intended to be limiting in any way. In addition to the illustrative aspects, embodiments and features described above, additional aspects, embodiments and features will become apparent by reference to the drawings and the detailed description below.

### BRIEF DESCRIPTION OF THE DRAWINGS

FIG. 1 is a plan view illustrating a transfer apparatus of a semiconductor manufacturing apparatus applied with an automatic teaching apparatus for semiconductor manufacturing equipment according to an embodiment of the present disclosure, in an initial state.

FIG. 2 is a plan view illustrating a state where a robot of the transfer apparatus of the semiconductor manufacturing apparatus applied with the automatic teaching apparatus for semiconductor manufacturing equipment according to an embodiment of the present disclosure illustrated in FIG. 1, performs load port teaching.

FIG. 3 is a view sequentially illustrating teaching processes of the end effector of the robot, which are performed by a load port teaching unit according to an embodiment of the present disclosure.

FIG. 4 is a plan view illustrating a state where the end effector of the transfer apparatus of the semiconductor manufacturing apparatus applied with the automatic teaching apparatus for semiconductor manufacturing equipment according to an embodiment of the present disclosure, supplies a wafer to a buffer after teaching is completed.

FIG. 5 is a plan view illustrating a state where the robot of the transfer apparatus of the semiconductor manufacturing apparatus applied with the automatic teaching apparatus for semiconductor manufacturing equipment according to an embodiment of the present disclosure, performs station teaching.

FIG. 6 is a view sequentially illustrating teaching processes of the end effector of the transfer apparatus of the semiconductor manufacturing apparatus applied with the automatic teaching apparatus for semiconductor manufacturing equipment according to an embodiment of the present disclosure, which are performed by a station teaching unit.

FIG. 7 is a plan view illustrating a state where the end effector of the transfer apparatus of the semiconductor manufacturing apparatus applied with the automatic teaching apparatus for semiconductor manufacturing equipment according to an embodiment of the present disclosure, supplies a wafer to a station after teaching is completed.

FIG. 8 is a cross-sectional view illustrating a state where a dummy port of the transfer apparatus of the semiconductor manufacturing apparatus applied with the automatic teaching apparatus for semiconductor manufacturing equipment according to an embodiment of the present disclosure, is positioned and fixed into a load port.

FIG. 9 is a plan view illustrating a state where the robot of the transfer apparatus of the semiconductor manufacturing apparatus applied with an automatic teaching apparatus for semiconductor manufacturing equipment according to another embodiment of the present disclosure, performs load port teaching.

FIG. 10 is a plan view illustrating a state where the robot of the transfer apparatus of the semiconductor manufacturing apparatus applied with an automatic teaching apparatus for semiconductor manufacturing equipment according to another embodiment of the present disclosure, performs station teaching.

FIGS. 11A and 11B are views illustrating a transfer apparatus according to a modified example of the present disclosure. FIG. 11A illustrates a robot accessing a wafer carrier (FOUP) 460 disposed in a second load port 420-2, and FIG. 11B illustrates a robot accessing a teaching jig 500 disposed in a first load port 420-1.

FIG. 12 is a view illustrating the wafer carrier (FOUP) disposed in a load port of the transfer apparatus.

FIG. 13 is a view illustrating a teaching jig disposed in the load port of the transfer apparatus, in which a plate-shaped substrate having specific features is accommodated therein.

FIG. 14 is a side cross-sectional view for explaining a state of mounting a teaching jig on the load port installed in the transfer apparatus.

FIG. 15 is a view illustrating an example of a first arrangement position in which a specific feature is disposed within a teaching jig.

FIG. 16 is a view illustrating an example of a second arrangement position in which a specific feature is positioned within the teaching jig.

FIG. 17 is a view illustrating a teaching jig in which plate-shaped substrates provided with specific features are hierarchically accommodated in multiple stages.

### DESCRIPTION OF EMBODIMENTS

In the following detailed description, reference is made to the accompanying drawings, which form a part of the present disclosure. The exemplary embodiments described in the detailed description, drawings, and claims are not intended to be limiting. Other embodiments may be utilized, and other changes may be made, without departing from the scope or spirit of the subject matter presented herein.

Hereinafter, embodiments of an automatic teaching apparatus for semiconductor manufacturing equipment according to the present disclosure will be described with reference to the accompanying drawings. In the procedure, the thicknesses of lines or the sizes of elements may be exaggerated for clarity of illustration. Furthermore, terms used herein are terms defined in consideration of functions in the present disclosure, and may differ depending on a user or operator's intention or custom. Thus, the definitions of the terms will be determined on the basis of the contents of the present specification.

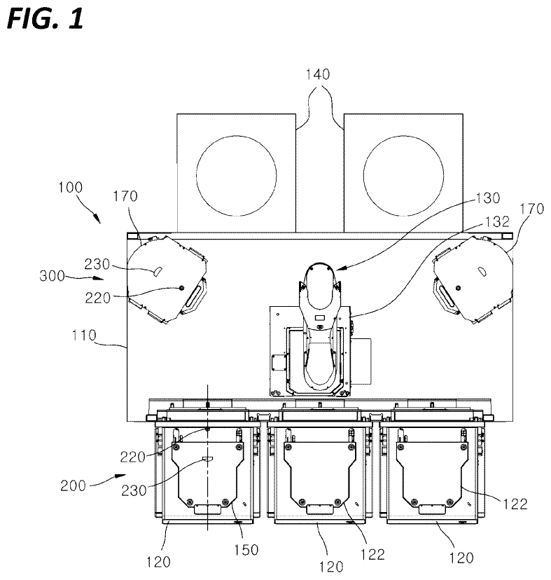

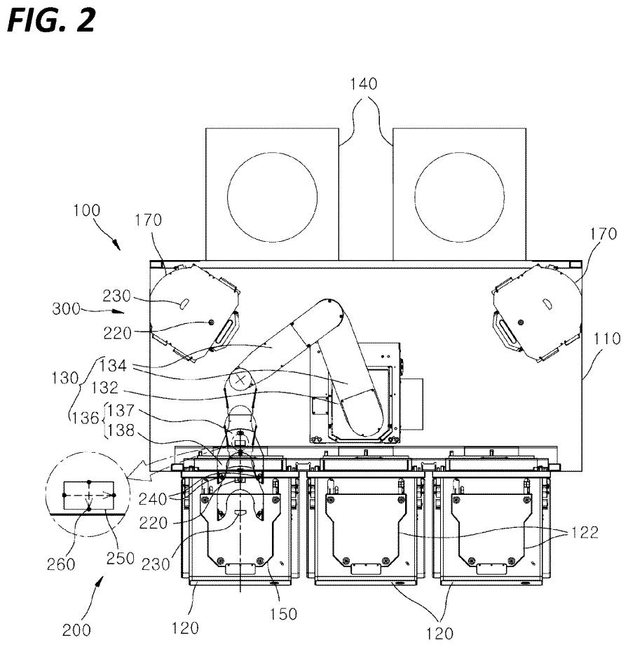

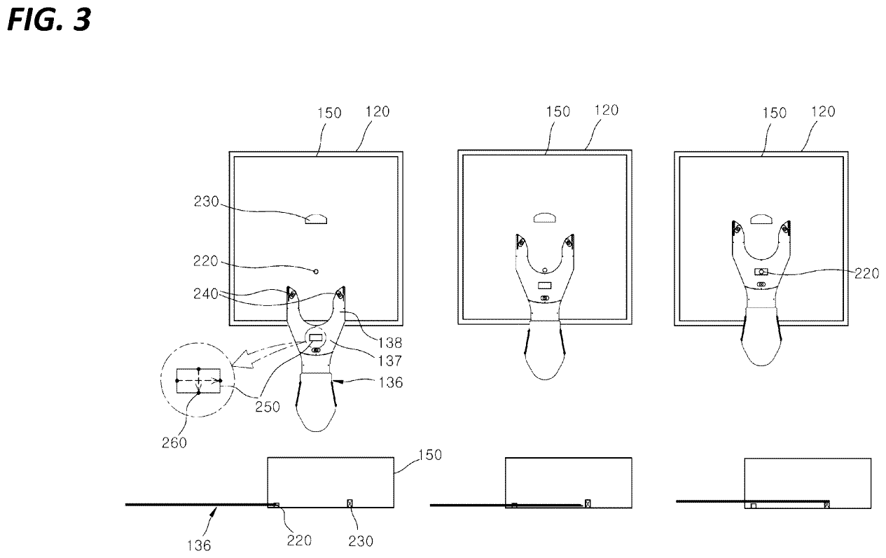

FIG. 1 is a plan view illustrating a transfer apparatus of a semiconductor manufacturing apparatus applied with an automatic teaching apparatus for semiconductor manufacturing equipment according to an embodiment of the present disclosure, in an initial state. FIG. 2 is a plan view illustrating a state where a robot of the transfer apparatus of the semiconductor manufacturing apparatus applied with the automatic teaching apparatus for semiconductor manufacturing equipment according to an embodiment of the present disclosure, performs load port teaching. FIG. 3 is a view sequentially illustrating teaching processes of the end effector of the robot, which are performed by a load port teaching unit according to an embodiment of the present disclosure.

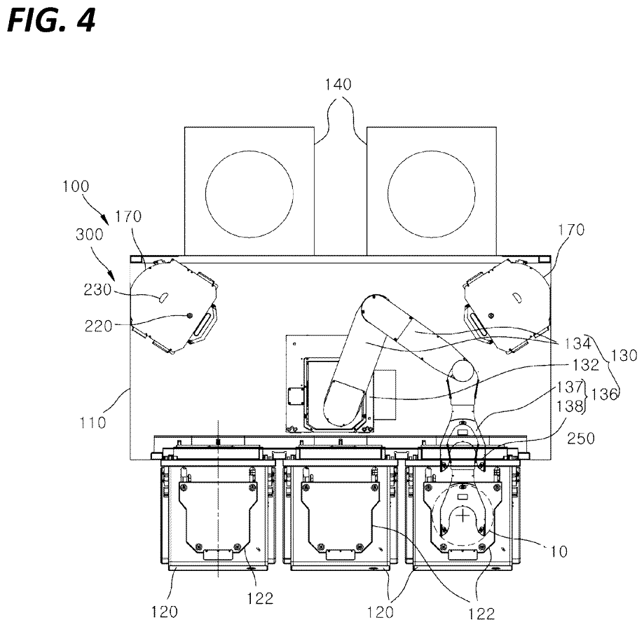

FIG. 4 is a plan view illustrating a state where the end effector of the transfer apparatus of the semiconductor manufacturing apparatus applied with the automatic teaching apparatus for semiconductor manufacturing equipment according to an embodiment of the present disclosure, supplies a wafer to a buffer after teaching is completed.

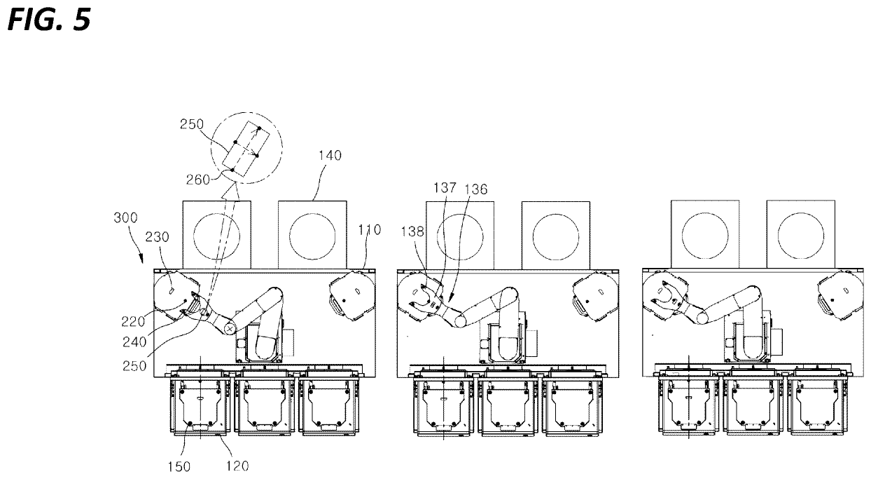

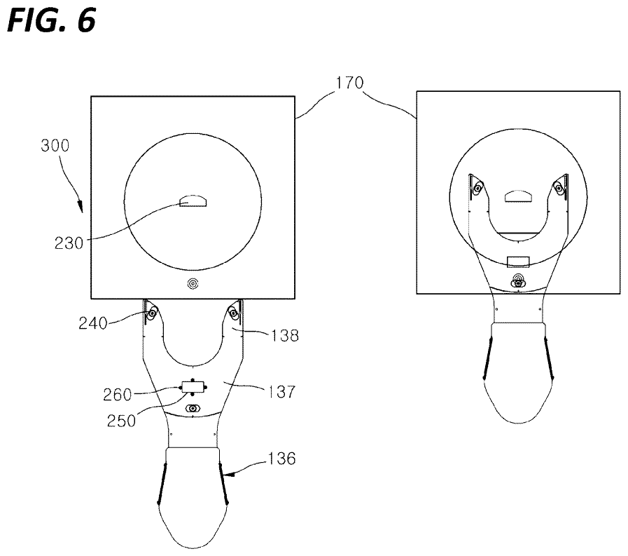

FIG. 5 is a plan view illustrating a state where the robot of the transfer apparatus of the semiconductor manufacturing apparatus applied with the automatic teaching apparatus for semiconductor manufacturing equipment according to an embodiment of the present disclosure, performs station teaching. FIG. 6 is a view sequentially illustrating teaching processes of the end effector of the transfer apparatus of the semiconductor manufacturing apparatus applied with the automatic teaching apparatus for semiconductor manufacturing equipment according to an embodiment of the present disclosure, which are performed by a station teaching unit.

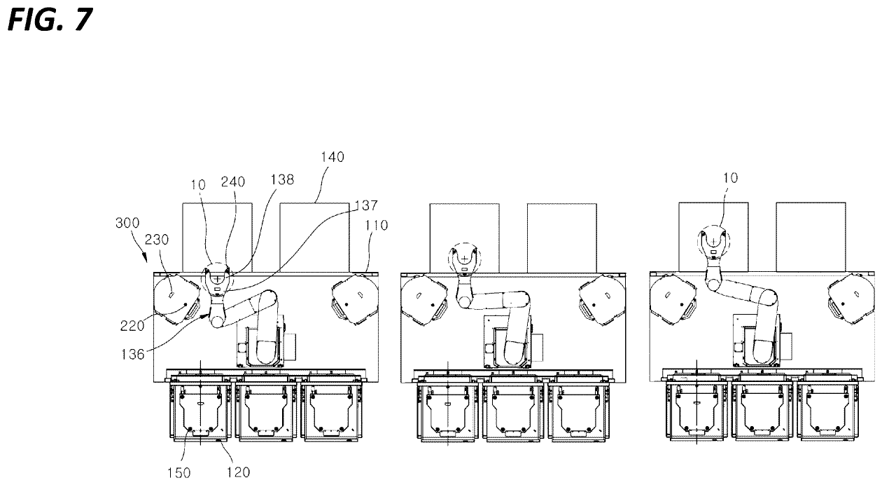

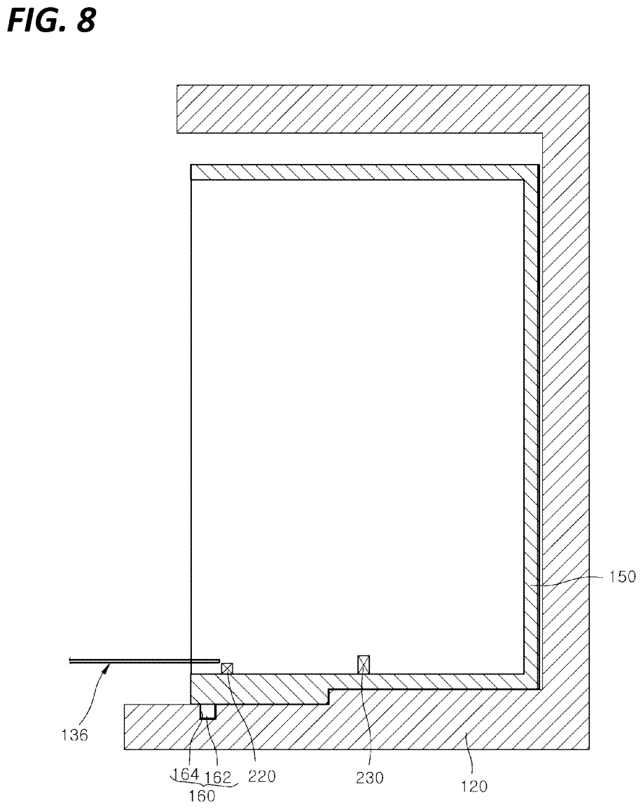

FIG. 7 is a plan view illustrating a state where the end effector of the transfer apparatus of the semiconductor manufacturing apparatus applied with the automatic teaching apparatus for semiconductor manufacturing equipment according to an embodiment of the present disclosure, supplies a wafer to a station after teaching is completed. FIG. 8 is a cross-sectional view illustrating a state where a dummy port of the transfer apparatus of the semiconductor manufacturing apparatus applied with the automatic teaching apparatus for semiconductor manufacturing equipment according to an embodiment of the present disclosure, is positioned and fixed into a load port.

Referring to FIGS. 1 to 8, a transfer apparatus 100 of a semiconductor manufacturing apparatus applied with an automatic teaching apparatus of wafers 10 for semiconductor manufacturing equipment according to an embodiment of the present disclosure includes an equipment front end module (EFEM) 110, a transfer robot 130, a load port (LP) 120, a load port teaching unit 200, stations 140, and a station teaching unit 300.

The EFEM 110 has a polygonal shape in plane and maintains a clean environment in an inside thereof to provide a clean space in which the wafer 10 is transported without contamination. For convenience of explanation, the EFEM 110 is illustrated as having a rectangular shape in plane.

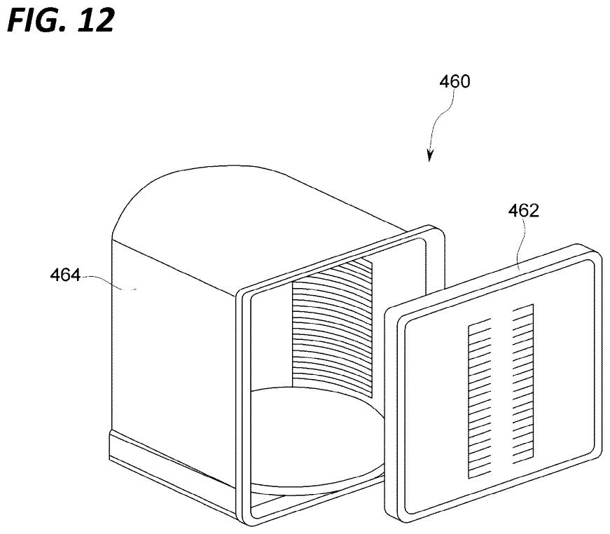

In addition, one or more load ports 120 are disposed along an edge of one side of the EFEM 110, and each load port is connected with the inside of the EFEM 110. In this case, the load ports 120 serve to allow a wafer carrier (herein, also referred to as a front opening unified pod (FOUP) or buffer) for loading the processed wafers 10 in an inside thereof to become in a state where the robot may access the wafer from the inside of the EFEM. For convenience of explanation, three load ports 120 are disposed along an edge of one side of the EFEM 110. The leftmost load port 120 in FIG. 1 is referred to as a specific load port by installing a detection pin 220 and a semicircular block 230 in a dummy port 150 accommodated in the leftmost load port 120, and the center and rightmost load ports 120 are loaded with buffers 122. The buffer 122 has an openable and closable door and accommodates the wafers in wafer slots (wafer mounting stages) formed in multiple stages and thus, corresponds to a wafer carrier (FOUP) for accommodating the wafers therein. As illustrated in FIG. 12, a FOUP 460 has a housing 464 having an opening in one surface thereof and a cover 462 for opening and closing the opening, and inside the housing, the wafer mounting stages for accommodating the wafers are installed in multiple stages. In some cases, the load port 120 is described and illustrated as accommodating (loading) the buffer 122 in its inside space, but is not limited thereto, and the buffer 122 may be mounted on a placement table (stage) of the load port.

In addition, one or more stations 140 are disposed along an edge of the other side of the EFEM 11, and each station 140 is connected with the inside of the EFEM 110. For example, after the wafer 10 prior to processing is introduced, the station 140 transitions to a vacuum state where an internal gas is evacuated or a pressure state that is approximately equal to atmospheric pressure by purging an inert gas, thereby allowing a wafer processing apparatus (not illustrated) to exchange the wafer 10 through the station 140. Thus, the station 140 has a hollow interior. For convenience of explanation, two stations 140 are illustrated as being provided along the edge of the other side of the EFEM 110.

The transfer robot 130 may be positioned and fixed inside the EFEM 110, or may be moved along a set trajectory, and serves to directly transfer the wafer 10 between the load port 120 and the station 140. That is, the transfer robot 130 carries the wafer from the buffer 122 (wafer carrier) loaded in the load port 120 into the EFEM 110 to deliver the wafer to the station 140, and delivers the carried wafer 10 from the station 140 to the buffer 122 (wafer carrier) in the load port 120. For convenience of explanation, the transfer robot 130 is illustrated as being fixed to the inside of the EFEM 110.

Specifically, in this embodiment, the transfer robot 130 includes a body 132, a middle link arm 134, and an end effector 136.

The body 132 supports the middle link arm 134 and the end effector (hand) 136 while being secured to an inner bottom of the EFEM 110.

One side of the middle link arm 134 is pivotably connected to the body 132 by a set angle. In this case, the middle link arm 134 may be provided as a single link arm or a plurality of link arms connected to each other.

In addition, the end effector (hand) 136 is pivotably linked to the middle link arm 134 to be movable in both horizontal and vertical directions, and is provided to be initially folded, or to be unfolded (expand) for loading or unloading of the wafer 10.

Further, the end effector 136 includes a base pad 137 and forks 138.

At least a top surface of the base pad 137 has a substantially planar shape to meet and stably support a portion of the wafer 10.

A pair of the forks 138 extend from the base pad 137 to the front side to contact and support the wafer 10 while reducing a load of the end effector 136. The base pad 137 and the forks 138 may be modified into various shapes.

Meanwhile, the load port teaching unit 200 serves to detect a fixed position of the end effector 136 in the state of unloading the wafer 10 (i.e., without the wafer 10 placed thereon), that is, a delivery position of the wafer 10 within the load port 120, such that the wafer 10 is placed in the fixed position within the load port 120.

To this end, the load port teaching unit 200 includes a detection pin 220, a semicircular block 230, front end sensors 240, a central hole portion 250, and a central sensor 260. The detection pin 220 and the semicircular block 230 are examples of teaching jig for teaching the delivery position of the wafer 10 to the transfer robot 130, and correspond to an example of specific features disposed to determine a relative positional relationship with the delivery position of the wafer 10. The front end sensor 240, the central hole portion 250, and the central sensor 260 are provided on the end effector (hand) 136 of the transfer robot 130.

The detection pin 220 protrudes from the inner bottom surface of the specific load port 120, the dummy port 150 or the EFEM 110 to correspond to a front edge or center of the wafer 10 in plane. Hereinafter, for convenience of explanation, it is assumed that the specific load port 120 includes the dummy port 150, and the detection pin 220 protrudes from the inner bottom surface of the dummy port 150. In this case, the detection pin 220 protrudes from a front edge of an inner bottom of the dummy port 150 where the end effector 136 enters. The detection pin 220 may be applied in various shapes and is not limited in size.

The semicircular block 230 protrudes from the inner bottom surface of the specific load port 120, the dummy port 150, or the EFEM 110 at a position spaced apart by a set distance along a straight line with the detection pin 220 in an entry direction of the end effector 136. In this case, the semicircular block 230 is illustrated as protruding from the inner bottom surface of the dummy port 150 from which the detection pin 220 protrudes. The semicircular block 230 may be applied in various shapes and is not limited in size and height.

As illustrated in FIG. 8, the dummy port 150 having the detection pin 220 and the semicircular block 230 formed on the inner bottom surface thereof is disposed in the load port 120 where an actual wafer carrier is mounted and has a shape of a housing having an opening through which the end effector 136 may enter.

Further, the front end sensors 240 are provided in a straight line to face each other at the pair of forks 138 extending from the base pad 137 of the end effector 136. That is, the front end sensors 240 are provided on front ends of the end effector (hand) 136 and are referred to as an example of first sensors herein. Thus, the end effector 136 includes a pair of front end sensors 240, where one front end sensor 240 is a light receiver and the other front end sensor 240 is a light emitter. Alternatively, the pair of front end sensors 240 may be limit sensors.

Thus, when the end effector 136 enters an inside of the dummy port 150, the detection pin 220 is positioned between the pair of forks 138.

In particular, the front end sensor 240 detects the position of the detection pin 220 between the corresponding forks 138 and detects and guides an entry position of the end effector 136 in a Y-direction and a Z-direction such that the end effector 136 is centered in the plane at a set height based on the detection pin 220 whose position is detected.

Here, the Y-direction refers to a direction in which the end effector 136 enters the dummy port 150, and the Z-direction refers a vertical direction.

The front end sensors 240 may be fixedly installed on the corresponding forks 138 in various ways.

Accordingly, the end effector 136 detects positions in the Y-direction and positions in the Z-direction of the pair of forks 138 with respect to the detection pin 220 and then, is positioned above the detection pin 220 so that it is prevented from colliding with the detection pin 220 during forward movement.

The central hole portion 250 is formed to penetrate through the base pad 137 such that the detection pin 220 is positioned therein when the end effector 136 positioned above the detection pin 220 moves forward by a set distance in the Y-direction and then, the pair of front end sensors 240 detects the semicircular block 230.

At this time, the central hole portion 250 is configured to have a size capable of securing a region in which the end effector 136 moves for teaching.

In addition, one or more central sensors 260 are provided in the base pad 137 along an edge of the central hole portion 250 to interact with the central hole portion 250 in an inward direction and position the end effector 136 in the X-direction and the Z-direction such that the detection pin 220 is set at a set position. As illustrated in FIG. 3, the central sensor 260 is arranged closer to a base end of the end effector 136 than the front end sensor 240 and arranged to traverse an opening of the central hole portion 250, and is referred to as an example of a second sensor. Two central sensors 260 are illustrated as being provided in the central hole portion 250. In this case, one central sensor has an optical axis parallel to an optical axis of the front end sensor 240 and is also referred to as an alpha sensor, and the other central sensor has an optical axis orthogonal to each of the optical axis of the one central sensor and the optical axis of the front end sensor 240, and is also referred to as a beta sensor. Alternatively, a single central sensor 260 may be provided, which has an optical axis orthogonal to the optical axis of the front end sensor 240.

That is, the end effector 136 moves forward in the Y-direction over the detection pin 220 and when the pair of front end sensors 240 detect the semicircular block 230, the forward movement of the end effector 136 is stopped. At this time, the detection pin 220 is positioned in an inside region of the central hole portion 250.

Thereafter, the central sensor 260 continuously detects the detection pin 220 such that the detection pin 220 is positioned at the set position (i.e., the center) of the central hole portion 250. In this case, the end effector 136 moves in the X-direction and the Z-direction to position the detection pin 220 in a central region of the central hole portion 250. That is, when the front end sensor 240 detects the semicircular block 230, the detection pin 220 enters the central hole portion 250. Here, “X-direction” refers to a direction perpendicular to the Y-direction.

At this time, a controller controls the movement of the end effector 136 by the motor force such that the detection pin 220 is positioned at a center between the pair of front end sensors 240 and the center of the central hole portion 250.

Finally, the detection pin 220 is positioned in an inner central region of the central hole portion 250 and at the same time, the semicircular block 230 is positioned at the center between the pair of forks 138. Accordingly, a teaching process of the end effector 136 with respect to the load port 120 is completed.

In this case, the central sensor 260 detects the detection pin 220 and teaches the position of the end effector 136, and the front end sensor 240 detects the semicircular block 230 and teaches the position of the end effector 136, so that the end effector 136 is controlled to be compositely positioned in the X, Y, and Z-directions by the motor force.

The dummy port 150 provided in the specific load port 120 for teaching may be different from, or identical to, the buffers 122 provided inside the other load ports 120.

When the dummy port 150 and the buffer 122 are different, after the teaching process is completed, the dummy port 150 is removed from the specific load port 120 and then, the buffer 122 is installed in the specific load port 120.

Next, the end effector 136 transfers the wafers 10 to the insides of all the load ports 120 or all the buffers 122 based on teaching values and then, unloads the wafers.

In particular, when the dummy port 150 is positioned inside the specific load port 120, the dummy port 150 is set at a fixed position with respect to the load port 120 by a first positioning unit 160. Additionally, the buffer 122 may be set at a fixed position inside the load port 120 by the first positioning unit 160.

Here, the first positioning unit 160 includes a first setting pin 162 and a first setting groove 164.

A plurality of first setting pins 162 protrude from lower surfaces of the dummy port 150 and the buffer 122.

Furthermore, the first setting groove 164 is recessed in the inner bottom surface of the load port 120 to accommodate the first setting pin 162 one-to-one. Accordingly, the dummy port 150 or the buffer 122 is positioned and fixed in the corresponding load port 120. Thus, the first setting pin 162 and the first setting groove 164 serve to secure the dummy port 150 (or buffer) to the load port 120, but are not limited thereto, and may be variously modified. For example, the first setting pin 162 may be provided on the bottom surface of the load port and the first setting groove 164 may be provided in the lower surface of the dummy port 150 (or buffer).

Consequently, before the end effector 136 transfers the wafer 10 to the inside of the load port 120 or the buffer 122 and unloads the wafer 10, only the end effector 136 enters the specific load port 120 or the dummy port 150 inside the specific load port 120. Then, the position of the detection pin 220 is detected by the front end sensor 240 and the central sensor 260 in sequence, and the position of the semicircular block 230 is detected by the front end sensor 240, so that the end effector 136 is taught to be positioned within the specific load port 120 or the dummy port 150.

Meanwhile, the station teaching unit 300 serves to detect a fixed position within the station 140 such that the end effector 136 in the state of unloading the wafer 10 places the wafer 10 in the fixed position within the station 140.

To this end, the EFEM 110 may include a dummy station 170 on an interior floor at a set position thereof, or may include a dummy station 170 inside a specific station 140. For convenience of explanation, for teaching of the wafer 10 within the station 140, the dummy station 170 of the same size as that of the station 140 is fixedly installed on the interior floor of the EFEM 110. The dummy station 170 may be secured to the EFEM 110 in a variety of ways.

In particular, the station teaching unit 300 has configurations identical to the limited configuration of the load port teaching unit 200 described above for ease of manufacture and compatibility.

That is, the station teaching unit 300 includes the detection pin 220, the semicircular block 230, the front end sensors 240, the central hole portion 250, and the central sensors 260.

The detection pin 220 protrudes from an inner bottom surface of a specific station 140 or the dummy station 170 to correspond to a front edge or center of the wafer 10 in plane. For convenience of explanation, the dummy station 170 is illustrated as being provided on a set inner bottom surface of the EFEM 110.

The semicircular block 230 protrudes from the inner bottom surface of the specific station 140 or dummy station 170.

In this case, functions of the detection pin 220 and the semicircular block 230 are replaced with those described above. Furthermore, functions of the front end sensor 240, the central hole portion 250, and the central sensor 260 are replaced with those described above.

The detection pin 220 and the semicircular block 230 may also be provided on the inner bottom surface of the specific station 140.

Furthermore, a detailed description of performing a teaching process of the end effector 136 by the interactions of the detection pin 220, the semicircular block 230, the front end sensor 240, the central hole portion 250, and the central sensor 260 is replaced with those described above.

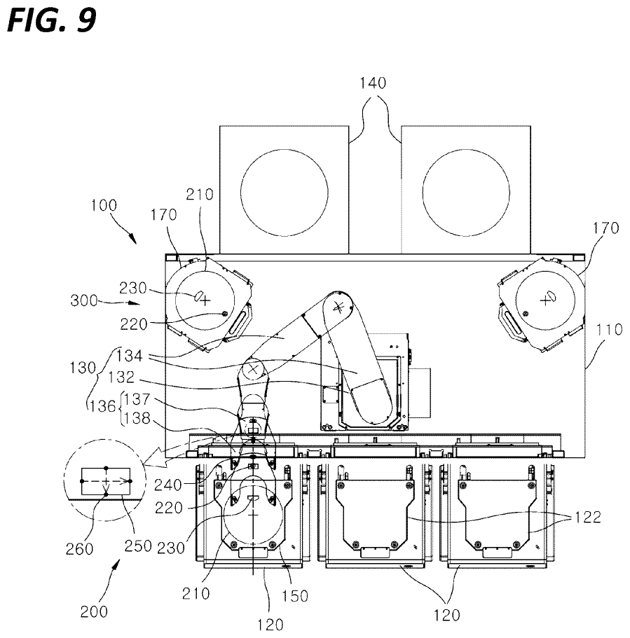

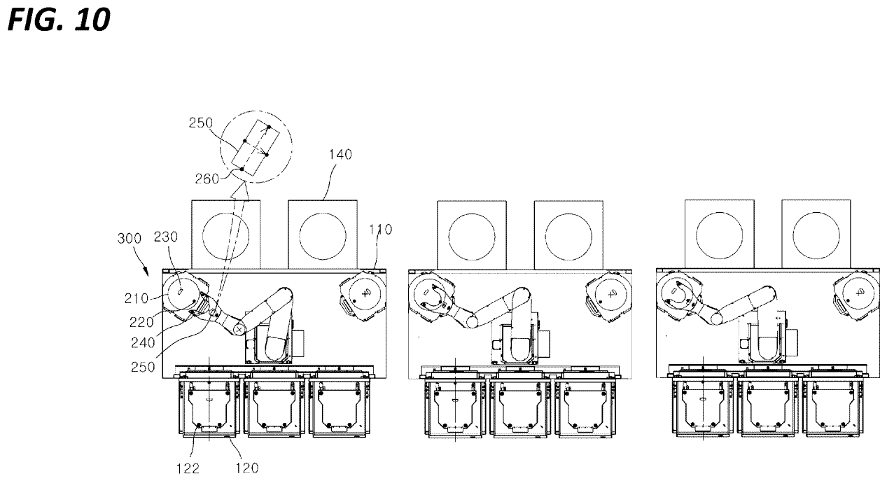

FIG. 9 is a plan view illustrating a state where a robot of an automatic teaching apparatus for semiconductor manufacturing equipment according to another embodiment of the present disclosure performs load port teaching. FIG. 10 is a plan view illustrating a state where a robot of an automatic teaching apparatus for semiconductor manufacturing equipment according to another embodiment of the present disclosure performs station teaching.

Referring to FIGS. 9 and 10, the transfer apparatus 100 of the semiconductor manufacturing apparatus applied with the automatic teaching apparatus of the wafers 10 for semiconductor manufacturing equipment according to another embodiment of the present disclosure includes an equipment front end module (EFEM) 110, a transport robot 130, a load port (LP) 120, a load port teaching unit 200, a station 140, and a station teaching unit 300.

At this time, the EFEM 110, the transfer robot 130, the load port 120, and the station 140 are replaced with those described above.

The load port teaching unit 200 includes a base plate 210, a detection pin 220, a semicircular block 230, front end sensors 240, a central hole portion 250, and central sensors 260.

The base plate 210 is placed in a fixed position on an inner bottom of a specific load port 120 or a dummy port 150 provided inside the specific load port 120. For convenience of explanation, the base plate 210 is installed in a fixed position on the inner bottom of the dummy port 150, but is not limited thereto. The base plate 210 may be installed at the same height as the wafer disposed in the buffer 122 within the dummy port 150.

The detection pin 220 and the semicircular block 230 according to one embodiment of the present disclosure protrude from the base plate 210. In particular, functions of the detection pin 220 and the semicircular block 230 are replaced with those described above in the one embodiment.

Accordingly, an installation direction of the base plate 210 needs to be set such that the detection pin 220 is positioned on an open front side of the dummy port 150. The base plate 210 may be modified into various shapes. For example, the base plate 210 may be a plate-shaped substrate or may be a substrate having the same diameter as an actual wafer.

In addition, the front end sensor 240, the central hole portion 250, and the central sensor 260 are replaced with those described above.

Additionally, the station teaching unit 300 is configured to be identical to the limited configuration of the load port teaching unit 200 according to this embodiment.

That is, the station teaching unit 300 includes a base plate 210, a detection pin 220, a semicircular block 230, front end sensors 240, a central hole unit 250, and a central sensor 260.

The base plate 210 is positioned and fixed on an inner bottom surface of the dummy station 170 that is fixed to a set position within the station 140, or the EFEM 110. For convenience of explanation, the base plate 210 is positioned and fixed on the inner bottom surface of the dummy station 170.

Further, the detection pin 220 and the semicircular block 230 protrude from the base plate 210. In particular, functions of the detection pin 220 and the semicircular block 230 are replaced with those described above in the one embodiment.

Accordingly, an installation direction of the base plate 210 needs to be set such that the detection pin 220 is positioned on the open front side of the dummy station 170. The base plate 210 may be molded into various shapes.

Furthermore, the front end sensors 240, the central hole portion 250, and the central sensor 260 may be replaced with those described above.

The embodiments disclosed herein are not limited to the above-described embodiments, but may be variously modified without departing from the spirit and technical idea.

In other words, while the previous embodiments have been exemplified using a case where three load ports 120 are installed along an edge of one side of the EFEM 110, a case where more than three load ports 120 are installed in the EFEM 110 may also be applied in the same manner. Also, while the detection pin 220 and the semicircular block 230 are installed in the previous embodiments, additional detection pins may be further installed Furthermore, while the previous embodiments exemplify a case where the buffer 122 serving as a wafer carrier and the dummy port 150 are loaded (accommodated) into an internal space of a specific load port 120, but a case where the buffer 122 serving as a wafer carrier and the dummy port 150 are mounted on a stage (placement table) of the load port 120 may also be applied in the same manner.

A modified example of the transfer apparatus is described below. In this modified example of the transfer apparatus, five load ports are installed along an edge of one side of the EFEM, a dummy port for teaching a wafer delivery position is mounted on the stage of the load port on which the wafer carrier may be mounted, and in addition to the detection pin 220 and the semicircular block 230 described in the previous embodiment, an additional detection pin may be installed in the dummy port. In describing the following modified example, the dummy port mounted on the load port is referred to as a teaching jig. To distinguish the modified example from the previous embodiments including the detection pin 220 and the semicircular block 230, the detection pin 220 and the semicircular block 230 referred to as an example of specific features in the previous embodiments are referred to as an example of first specific features in the modified example and an additionally introduced detection pin is referred to as an example of a second specific feature in the modified example. In addition, for ease of description, in the first specific features, the detection pin 220 is referred to as an example of a first detection portion and the semicircular block 230 is referred to as an example of a second detection portion, in some cases.

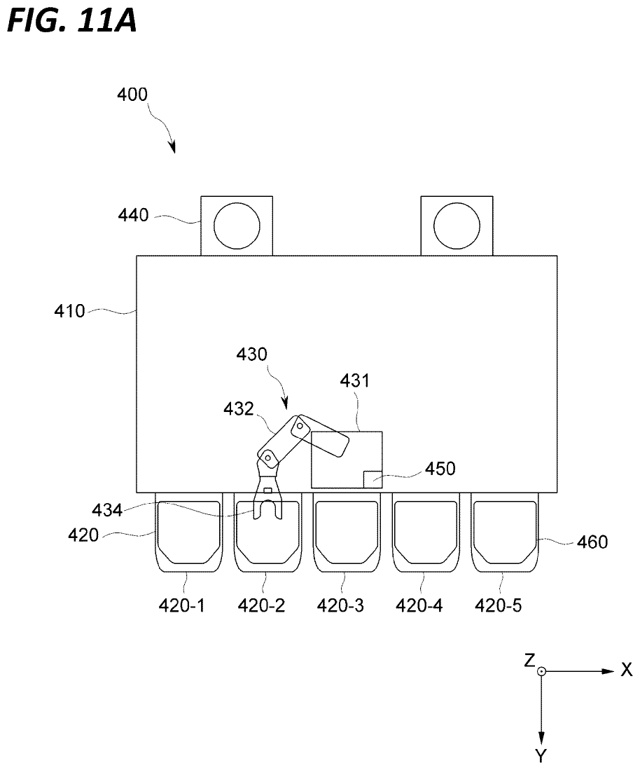

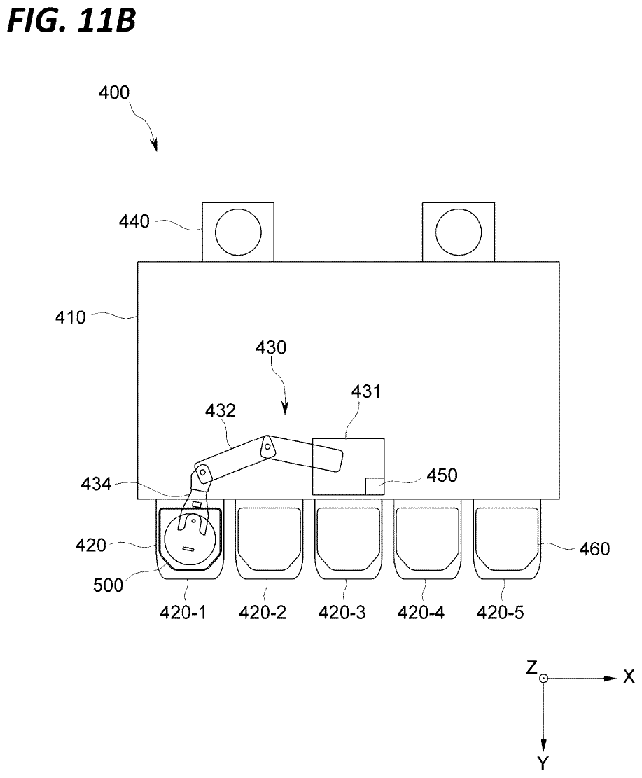

Referring to FIG. 11A, a transfer apparatus 400 according to this modified example includes an EFEM 410, load ports 420, a teaching jig 500, a robot 430, stations 440, and a robot control device 450. Configurations without changes compared to the previous embodiments will not be described.

As previously described, the EFEM 410 provides a clean space for transferring wafers while preventing contamination of the wafers by maintaining an inside of the EFEM 410 in a clean environment.

Five load ports 420 are disposed along an edge of one side opposite to an edge of the other side of the EFEM 410 on which the stations 440 are positioned. In the drawings, the load ports 420 are sequentially referred to as a first load port 420-1, a second load port 420-2, a third load port 420-3, a fourth load port 420-4, and a fifth load port 420-5, from the left to the right. On the placement table (stage) 470 of the load port 420, as illustrated in FIG. 12, a wafer carrier (FOUP) 460 capable of loading wafers in an inside thereof is mounted. The wafers accommodated in the wafer carrier 460 may be carried into the inside of the EFEM 410 by the robot 430, or conversely, wafers held on the robot 430 may be carried out from the wafer carrier 460.

As in the previous embodiments, one or more stations 440 are disposed along the edge of the other side opposite to the one side of the EFEM 410 on which the load ports 420 are positioned, and each station is connected to the inside of the EFEM 410.

As in the previous embodiment, the robot 430 performs delivery of the wafers from and to the wafer carrier 460 disposed in the load port 420 installed in the EFEM 410 forming a clean space.

The robot 430 includes a body 431 fixed to an inner bottom of the EFEM 410, an arm 432 having one side pivotably connected to the body 431, a hand 434 movable by the arm 432 in a horizontal direction and a vertical direction and configured to hold the wafer, and sensors provided on the hand 434. The hand 434 corresponds to the end effector 136 of the previous embodiment and has the same structure as the end effector 136, and therefore will not be described in detail.

In addition, the sensors provided on the hand 434 of the robot 430 include a first sensor provided at a front end of the hand and a second sensor provided closer to a base end of the hand than the first sensor, which have the same configurations and functions as those of the sensors (the front end sensor 240 and the central sensor 260) provided on the end effector of the previous embodiment. Thus, descriptions of the sensors will be omitted. That is, the front end sensor 240 of the previous embodiment corresponds to the first sensor in the modified example and the central sensor 260 of the previous embodiment corresponds to the second sensor in the modified example.

The teaching jig 500 of the modified example is mounted on the load port 120 installed in the EFEM 110 that forms the clean space in the previous embodiment, and teaches the robot 130 the delivery position of the wafer, in the same manner as the dummy port 150 having the detection pin 220 and the semicircular block 230, which are an example of specific features. The teaching jig 500 is disposed on the load port 420, as illustrated in FIG. 11B, and is configured to maintain a clean space of the transfer apparatus 400 in the same position as the delivery position of the wafer in the wafer carrier 460 by the robot 430.

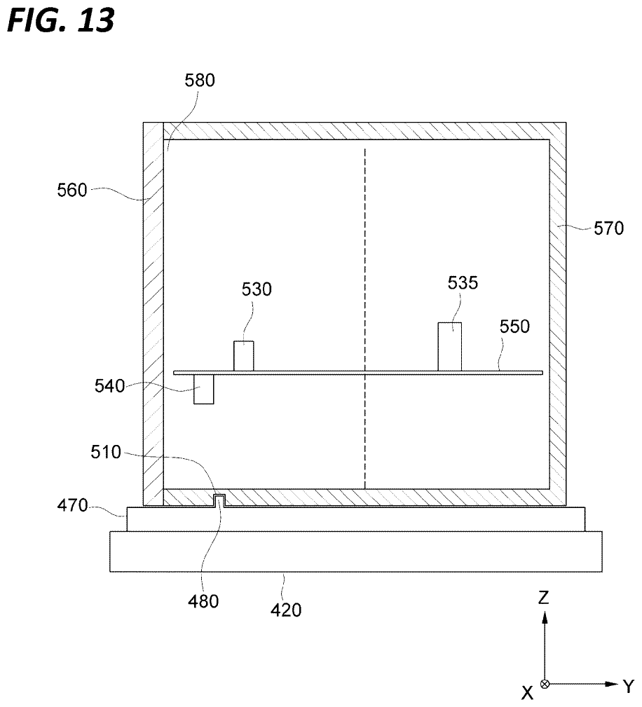

That is, the teaching jig 500 may be disposed on the load port 420 in a form of a housing capable of maintaining the clean space of the transfer apparatus 400, and is not limited in its shape. For example, the housing of the teaching jig 500 may have a shape similar to that of the wafer carrier (FOUP) illustrated in FIG. 12. Also, the teaching jig 500 may have the same shape as the wafer carrier. The teaching jig 500 includes an opening 580 in one surface of a housing 570 and further includes a cover 560 in the opening 580 for covering the opening 580, as illustrated in FIG. 13. The cover 560 of the teaching jig 500 is closed during transportation of the teaching jig 500, so that its interior may be maintained at a level of cleanliness that is maintained in the inside of the transfer device 400. The cover 560 is configured to be opened and closed by the load port 420 in a state where the teaching jig 500 is disposed on the load port 420, so that the clean space of the transfer apparatus may be maintained when a teaching operation of the wafer delivery position is performed by using the teaching jig 500.

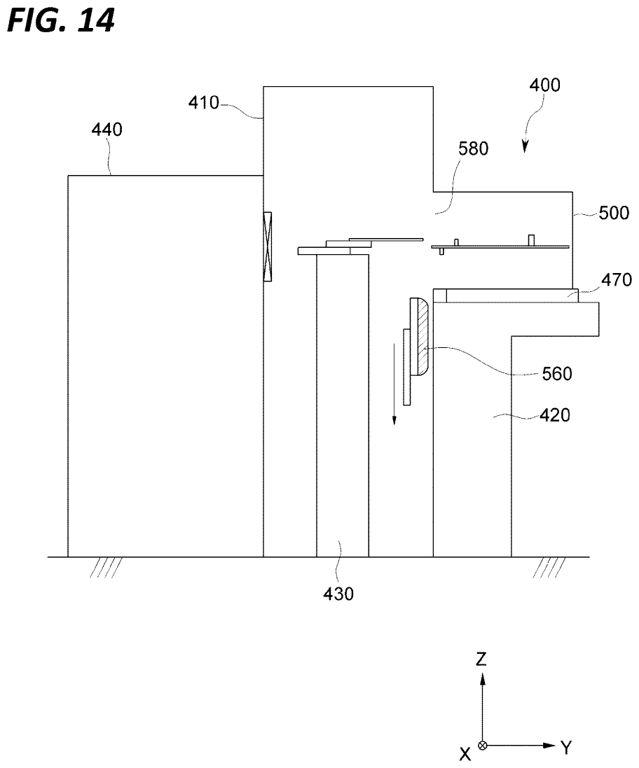

FIG. 14 illustrates a side cross-sectional view of the transfer apparatus 400 for explaining a state where the hand 434 of the robot 430 accesses the teaching jig 500 in the state where the teaching jig 500 is disposed on the load port 420 of the transfer apparatus 400 and the clean space of the transfer apparatus 400 is maintained. When the teaching jig 500 is mounted on the load port 420 in a state where the cover 560 is closed, as illustrated in FIG. 14, the cover 560 of the teaching jig 500 is separated from the housing 570 by an opening and closing mechanism of the load port 420 and is moved below the teaching jig 500 and then, opened, so that the hand 434 of the robot 430 may access an inside of the teaching jig 500 through the opening 580 of the teaching jig 500.

The housing 570 of the teaching jig 500 has a shape on a remaining surface of the housing 570 that allows the load port 420 to hold the teaching jig 500 when the teaching jig 500 is disposed on the load port 420. In FIG. 13, a lower surface of the housing 570 is illustrated as having a shape that allows the teaching jig 500 to be held on the load port 420. As an example of the shape, a setting groove 510 formed to be recessed in the lower surface of the housing 570 of the teaching jig 500 may be used. The setting groove 510 is accommodated one-to-one in a setting pin 480 provided at a position corresponding to the setting groove 510 on the stage 470 of the load port 420, so that the teaching jig 500 may be held on the load port 420.

Additionally, the teaching jig 500 includes specific features 530, 535, and 540 that are disposed to determine a relative positional relationship with the delivery position of the wafer within the wafer carrier 460. In this modified example, as an example of the specific features, the second detection pin 540, the first detection pin 530, and the semicircular block 535 may be sequentially disposed from the opening through which the hand of the robot 430 enters, as illustrated in FIG. 13, but the specific features are not limited thereto, and may be variously modified, as long as the hand 434 of the robot 430 may accurately recognize the delivery position of the wafer positioned within the wafer carrier.

In addition, in some cases, the first detection pin 530 and the semicircular block 535 may be described as an example of first specific features, and the second detection pin 540 may be described as an example of a second specific feature herein. Also, the first detection pin 530 and the semicircular block 535, which are an example of the first specific features, may be described as an example of the first detection portions and the second detection portion, respectively.

Additionally, specific features may be provided on plate-shaped substrates 550, for example. In this case, as illustrated in FIG. 13, the first detection pin 530 and the semicircular block 535 may protrude from one surface of the substrate 550, and the second detection pin 540 may protrude from the other surface of the substrate 550. The plate-shaped substrate 550 having the specific features formed thereon may be accommodated at a position corresponding to a wafer accommodation position in an actual wafer carrier 460 within the teaching jig 500 which has a similar shape to that of the wafer carrier 460. The plate-shaped substrate 550 may be a substrate having the same diameter as the actual wafer.

The first specific features 530 and 535 and the second specific feature 540 are disposed such that their positions relative to each other may be determined. The second specific feature 540 is positioned closer to the cover 560 of the teaching jig 500 compared to the first specific features 530 and 535. As described above, in this modified example, the detection pin 530 and the semicircular block 535 formed on the one surface of the plate-shaped substrate 550 are used as an example of the first specific features, and the detection pin 540 formed on the other surface of the plate-shaped substrate 550 is used as an example of the second specific feature, but the first specific feature and the second specific feature are not limited thereto, and may be variously changed.

In addition, the teaching jig 500 has a first arrangement position and a second arrangement position that is different from the first arrangement position, as arrangement positions for disposing the first specific features 530 and 535 and the second specific feature 540 when viewing the teaching jig 500 in plan view.

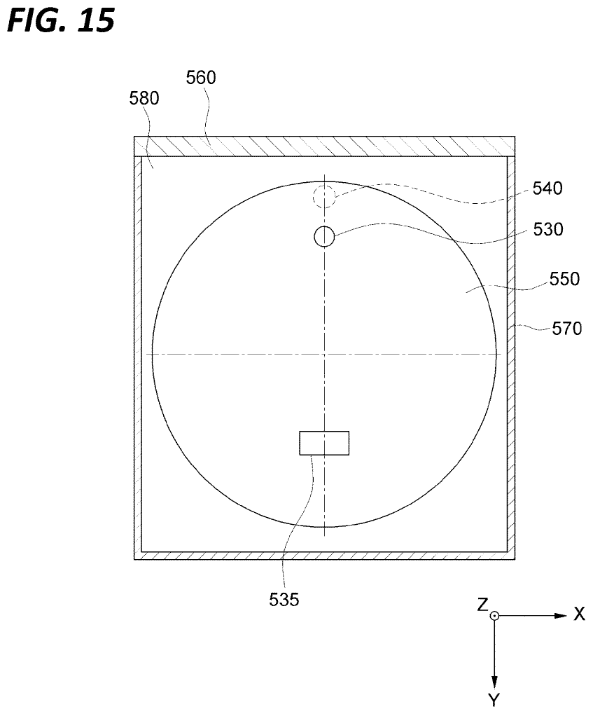

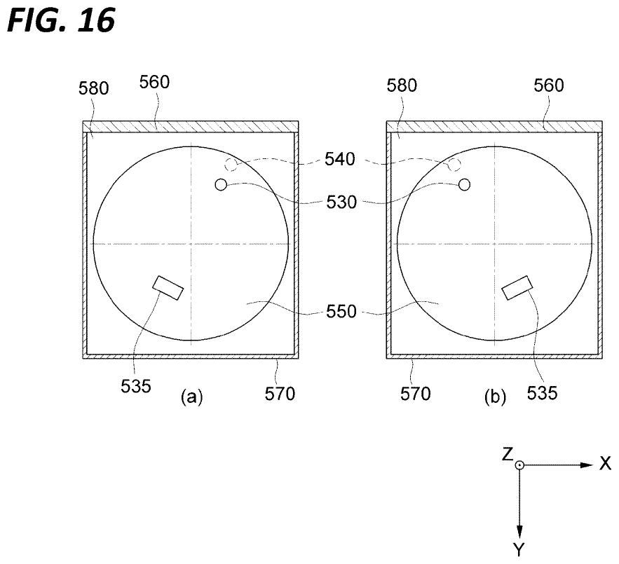

FIG. 15 illustrates an example of the first arrangement position and FIG. 16 illustrates an example of the second arrangement position. When the teaching jig 500 is disposed on the load ports other than outermost load ports among the plurality of load ports 420, for example, on the second to fourth load ports 420-2, 420-3, and 420-4, and the hand 434 accesses from the opening 580 of the teaching jig 500 while an angle of an axial line of the hand 434 with respect to the opening 580 maintains approximately a right angle, as viewed in plan view, the first specific features 530 and 535 and the second specific feature 540 as illustrated in FIG. 15 are disposed in the first arrangement position arranged in a direction orthogonal to the opening 580 of the teaching jig 500.

Meanwhile, when the teaching jig 500 is disposed on the outermost load port among the plurality of load ports 420, for example, the first load port 420-1 or the fifth load port 420-5, and the hand 434 accesses from the opening 580 of the teaching jig 500 while the angle of the axial line of the hand 434 with respect to the opening 580 does not maintain approximately a right angle, the specific features as illustrated in FIG. 16 are disposed in the second arrangement position arranged in a direction not perpendicular but inclined with respect to the opening 580 of the teaching jig 500.

When the wafer carrier 460 is disposed on the first load port 420-1 or the fifth load port 420-5, the angle of the axial line of the hand 434 with respect to the opening 580 of the teaching jig 500 may not be a right angle due to limitations in lengths of the arm 432 and the hand 434 of the robot 430. Accordingly, the hand 434 entering the wafer carrier 460 disposed on the outermost load port, such as the first load port 420-1 or the fifth load port 420-5, accesses the wafer carrier 460 slantingly at a certain angle rather than being perpendicularly.

Consequently, the first specific features 530 and 535 and the second specific feature 540 of the teaching jig 500 are positioned in an arrangement position based on an angle of the axial line of the hand 434 with respect to the opening 580 of the teaching jig 500. In this modified example, the axial line of the hand 434 means a line connecting the center of a sensing line formed by the front end sensors 240 provided at a front end of the hand 434, the center of the central hole portion 250 provided at a base end of the hand 434, and the axis of rotation of the hand 434.

Furthermore, in the second arrangement position, a surface on which the first specific features 530 and 535 are positioned and a surface on which the second specific feature 540 is positioned are different. That is, in the second arrangement position as illustrated in FIG. 16, the first detection pin 530 and the semicircular block 535, which are an example of the first specific features, are positioned on the one surface of the substrate 550, while the second detection pin 540, which is an example of the second specific feature, is positioned on the other surface of the substrate 550.

Additionally, in the first arrangement position as illustrated in FIG. 15, the second detection pin 540, which is an example of the second specific feature, may be omitted.

The teaching jig 500 having the specific features disposed in each arrangement position is disposed in the load port 420 to be taught according to the corresponding arrangement position, i.e., the teaching jig 500 having the specific features disposed in the first arrangement position is disposed in the second to fourth load ports 420-2, 420-3, and 420-4, and the teaching jig 500 having the specific features disposed in the second arrangement position is disposed in the first load port 420-1 or the fifth load port 420-5, so that teaching of the delivery position of the wafer in the wafer carrier 460 disposed in each load port 420 may be performed.

A method for detecting the first specific features 530 and 535 and the second specific feature 540 using the front end sensors 240 and the central sensor 260 provided on the hand 434 of the robot 430 will be described later.

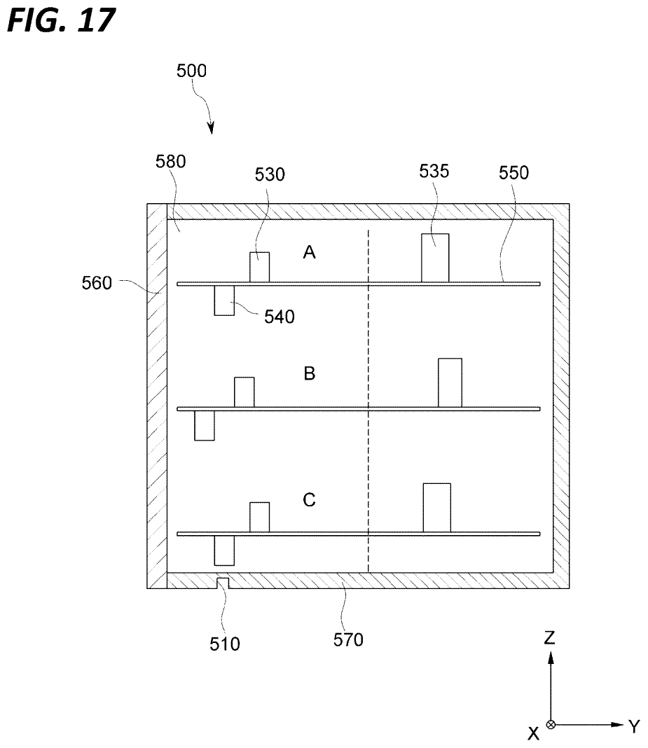

In addition, a plurality of plate-shaped substrates 550 having specific features may be provided within the teaching jig 500 as illustrated in FIG. 17. For example, by accommodating the plate-shaped substrates 550 in a plurality of accommodation positions for wafers within the teaching jig 500, a plurality of specific features may be hierarchically disposed in multiple stages within the teaching jig 500. In this case, the accommodation position of each plate-shaped substrate 550 corresponds to a height of the wafer to be accommodated within the wafer carrier.

Furthermore, when the plurality of plate-shaped substrates 550 having the specific features are accommodated within a single teaching jig 500 as described above, the arrangement position of the specific features on each plate-shaped substrate 550 may be different. For example, a bottommost plate-shaped substrate 550-C may have specific features disposed in the second arrangement position as illustrated in part (a) of FIG. 16, a plate-shaped substrate 550-B positioned above the bottommost plate-shaped substrate 550-C may have specific features disposed in the first arrangement position as illustrated in FIG. 15, and a topmost plate-shaped substrate 550-A may have specific features disposed in the second disposition as illustrated in part (b) of FIG. 16. In this manner, by accommodating a plurality of the substrates 550-A, 550-B, and 550-C having the specific features whose arrangement positions are different within a single teaching jig 500, it is unnecessary to provide multiple teaching jigs for teaching operations based on the positions of the load ports 420.

The first specific features 530 and 535 may include a first detection portion 530 and a second detection portion 535. In FIG. 13, as in previous embodiments, a first detection pin protruding from a surface of the substrate is used as an example of the first detection portion 530, and a semicircular block protruding from the same surface as that of the first detection pin is used as an example of the second detection portion 535.

As illustrated in FIG. 13, the first detection portion 530 is positioned closer to the cover 560 of the teaching jig 500 than the second detection portion 535, and the second detection pin which is an example of the second specific feature 540, is positioned closer to the cover 560 of the teaching jig 500 than the first detection portion 530. The second detection portion 535 is disposed in a position spaced apart from the first detection portion 530 by a predetermined distance in a direction in which the hand 434 enters, and is also disposed in a position where a gap between a side wall of the housing 570 of the teaching jig 500 and the hand 434 is secured when detected by the front end sensor 240 disposed at the front end of the hand 434 of the robot 430. The predetermined distance is determined by a distance between the front end sensor 240 (an example of the first sensor) provided at the front end of the hand 434 of the robot 430 and the central sensor 260 (an example of the second sensor) provided to traverse the central hole portion 250 formed at the base end of the hand 434 of the robot 430. Specifically, the predetermined distance corresponds to a distance between a central position of the central hole portion 250 and a straight line formed by the light emitter and the light receiver of the front end sensors 240. That is, the first detection portion 530 and the second detection portion 535 have a relative positional relationship such that the central sensor 260 may detect the first detection portion 530 and at the same time, the front end sensor 240 may detect the second detection portion 535.

Thus, when the front end sensor 240 detects the second detection portion 535, the first detection portion 530 may be positioned in an inner region of the central hole portion 250 and detected by the central sensor 260. Since the first detection portion 530 enters an inside of the central hole portion 250 by the movement of the hand 434, the hand 434 does not collide with the first detection portion 530. Furthermore, since the second specific feature 540, which is away from the central hole portion 250 of the hand 434, is positioned on a surface different from that of the first detection portion 530, the second specific feature 540 does not interfere with the hand 434 when the first detection portion 530 and the second detection portion 535 are detected.

The robot control device 450 of this modified example is a device for performing detection of the sensors 240 and 260 provided on the hand 434 and movement control of the hand 434. The robot control device 450 operates the hand 434 to detect the second specific feature 540 of the teaching jig 500 disposed on the load port 420 of the transfer apparatus 400 by the first sensor 240, moves the hand 434 to the first specific features 530 and 535 of the teaching jig 500 based on a detected position of the second specific feature 540 to detect the first specific features 530 and 535 by the first and second sensors 240 and 260, and obtain the delivery position of the wafer based on positions of the first specific features 530 and 535.

In other words, when the teaching jig 500 is mounted on the load port 420 of the transfer apparatus 400 and the cover 560 of the teaching jig 500 is opened by the load port 420, the robot control device 450 allows the hand 434 of the robot 430 to enter the inside of the teaching jig 500 through the opening 580 of the teaching jig 500, detects the second specific feature 540 installed on the teaching jig 500 by the first sensor 240, moves the hand 434 to a position where the first sensor 240 may detect the second detection portion 535 of the first specific feature and the second sensor 260 may detect the first detection portion 530 of the first specific feature to detect the positions of the first and second detection portions, thereby storing the delivery position of the wafer.

FIGS. 11A and 11B illustrate that the robot control device 450 is installed integrally with the robot 430, but is not limited thereto, and the robot control device 450 may be installed separately from the robot 430.

When five load ports 420 are installed along the edge of one side of the EFEM 410, as in this modified example, due to limitations to an internal space of the EFEM 410 and lengths of the arm 432 and hand 434 of the robot 430, the hand 434 may not enter the wafer carrier 460 disposed on the first load port 420-1 in a state of being perpendicular to the opening as illustrated in FIG. 11B, so that the robot control device 450 controls the hand 434 to enter the wafer carrier 460 disposed on the first load port 420-1 in a state where the axial line of the hand 434 is inclined to the opening of the first load port 420-1. This is also the same when the wafer carrier 460 is disposed on the fifth load port 420-5. However, even when the wafer carrier 460 is disposed on the first or fifth load port 420-1 or 420-5, it is possible to automatically teach the delivery position of the wafer in the wafer carrier while maintaining a clean space by using the teaching jig 500 of this modified example.

The following describes a teaching operation using the teaching jig 500 of this modified example.

The teaching jig 500 is disposed on the load port 420 formed on the edge of the one side of the EFEM 410. The teaching jig 500 may be automatically disposed by an overhead hoist transport (OHT) or an automated guided vehicle (AGV). The setting groove 510 provided in the bottom surface of the housing 570 of the teaching jig 500 engages with the setting pin 480 provided on the stage 470 of the load port 420, so that the teaching jig 500 is held on the load port 420.

When the teaching jig 500 is held on the load port 420, the cover 560 of the teaching jig 500 is opened in a state where the clean space of the transfer apparatus 400 maintains. An exemplary form of opening the cover 560 of the teaching jig 500 by the load port 420 may be provided with reference to FIG. 14, but is not limited thereto. When the cover 560 of the teaching jig 500 is opened, the robot control device 450 controls the robot 430 installed inside the EFEM 410 to allow the hand 434 to enter the inside of the teaching jig 500 through the opening 580 of the teaching jig 500.

As the hand 434 passes through the opening 580 of the teaching jig 500 and accesses the inside of the teaching jig 500, the second specific feature 540 of the teaching jig 500 that is positioned closest to the opening 580 is detected by the first sensor 240 provided at the front end of the hand 434. When the second specific feature 540 is detected, the robot control device 450 adjusts the position of the hand 434 in the X-direction, the Y-direction, and the Z-direction such that the hand 434 is positioned at the center of the first sensors 240 in plane and at a set height based on a detected position of the second specific feature 540. The Y-direction refers to a direction perpendicular to the opening of the teaching jig 500, the X-direction refers to a direction perpendicular to the Y-direction when viewed in plan view, and the Z-direction refers to a vertical direction of the teaching jig 500.

Thereafter, the robot control device 450 moves the hand 434 in the Y-direction and the Z-direction to detect the first specific features 530 and 535 formed on the opposite surface of the plate-shaped substrate 550. At this time, the position of the hand 434 may further be adjusted to prevent the hand 434 from colliding with the side wall of the housing 570 of the teaching jig 500 when the hand enters the teaching jig 500 for detection of the first and second specific features 530 and 535. As described above, when using the second specific feature 540 that is closer to the opening 580 of the teaching jig 500 than the first specific features 530 and 535 that are disposed at a position closer to an actual wafer delivery position (position to be taught), the hand 434 may safely access the first specific features 530 and 535 without interfering with surrounding portions thereof, such as the side wall of the housing 570 of the teaching jig 500. However, when the second specific feature is not provided in the teaching jig 500, an operation of detecting the second specific feature 540 described above may be omitted.

Thereafter, the robot control device 450 moves the hand 434 to the inside of the teaching jig 500 while maintaining the angle of the axial line of the hand 434 with respect to the opening 580 to detect the first and second specific features 530 and 535 by the first sensor 240 and the second sensor 260 and store the delivery position where the hand 434 delivers the wafer in the wafer carrier 460. This operation is substantially the same as the operation described in the previous embodiment.

That is, by moving the hand 434 while maintaining the angle of the axial line of the hand 434 with respect to the opening 580, the first detection portion 530 of the first specific features 530 and 535 is positioned between the first sensors 240 provided at the front end of the hand 434, and the position of the first detection portion 530 is detected. When the position of the first detection portion 530 is detected, the robot control device 450 adjusts the position of the hand 434 such that the hand 434 is positioned at the center of the first sensors 240 in plane and at a set height based on a detected position of the first detection portion 530. The hand 434 moves in the Z-direction to prevent its colliding with the first detection portion 530 during a forward movement thereof, and then, advances while maintaining the angle of the axial line of the hand 434, so that the second detection portion 535 of the first specific features 530 and 535 is positioned between the first sensors 240 provided at the front end of the hand 434, and the second detection portion 535 is detected. When the second detection portion 535 is detected by the first sensor 240 in this manner, a predetermined distance between the first detection portion 530 and the second detection portion 535 corresponds to a distance between a straight line formed by the first sensors 240 at the front end of the hand 434 and the central position of the central hole portion 250. Thus, the first detection portion 530 of the first specific features is positioned in the central hole portion 250 of the hand 434, and the first detection portion 530 may be detected by the second sensor 260 provided to traverse the central hole portion 250.

At this time, the robot control device 450 controls the hand 434 such that the first detection portion 530 is positioned at the central position of the central hole portion 250. When the first detection portion 530 is positioned at the central position of the central hole portion 250 of the hand 434, the corresponding position of the hand 434 is determined as the delivery position where the hand 434 delivers wafers within the wafer carrier 460, and the robot control device 450 stores the corresponding position.

Thereafter, the robot control device 450 controls the robot 430 to deliver wafers to and from the wafer carrier 460 disposed on the load port 420 based on the stored position.

Drawing symbols (not described) are replaced with those described above.

From the foregoing, it will be understood that various embodiments of the present disclosure are described herein for purposes of illustration, and that various changes may be made without departing from the scope and idea of the present disclosure. Accordingly, the various embodiments disclosed herein are not intended to limit the true scope and idea designated by the following claims.

What is claimed is:

1. An automatic teaching apparatus for semiconductor manufacturing equipment, the automatic teaching apparatus comprising:
an equipment front end module (EFEM);
one or more load ports provided along an edge of one side of the EFEM to be connected to an inside of the EFEM;
a transfer robot disposed in the inside of the EFEM and configured to transfer wafers to the one or more load ports by an end effector, to process the wafers; and
a load port teaching unit configured to detect a fixed position of the end effector in a state of unloading the wafer such that the wafer is placed in the fixed position within the load port.

2. The automatic teaching apparatus according to claim 1, wherein the end effector includes,
a base pad having at least a top surface formed in a planar shape; and
two forks extending to a front side of the base pad,
wherein the load port teaching unit includes,
a detection pin protruding from an inner bottom surface of a specific load port, a dummy port, or the EFEM to correspond to a front edge or a center of the wafer in plane;
a semicircular block protruding from the inner bottom surface of the specific load port, the dummy port, or the EFEM at a position spaced apart by a set distance along a straight line with the detection pin in an entry direction of the end effector;
a front end sensor provided on each of the forks in a straight line to face each other and configured to detect and guide an entry position of the end effector in a Y-direction and a Z-direction such that the detection pin is positioned at a center between the forks in plane and a set height;
a central hole portion penetrating through the base pad such that the detection pin is positioned therein when the forks move forward and the front end sensor detects the semicircular block; and
one or more central sensors provided on the base pad along an edge of the central hole portion to interact with the central hole portion in an inward direction and set a position of the end effector in an X-direction and a Z-direction such that the detection pin is set at the set position.

3. The automatic teaching apparatus according to claim 1, wherein the end effector includes,
a base pad having at least a top surface formed in a planar shape; and
two forks extending to a front side of the base pad,
wherein the load port teaching unit includes,
a base plate placed at a set position on an inner bottom of a specific load port, a dummy port, or the EFEM;
a detection pin protruding from a bottom surface of the base plate to correspond to a front edge or a center of the wafer in plane;
a semicircular block protruding from the base plate at a position spaced apart by a set distance along a straight line with the detection pin in an entry direction of the end effector;
a front end sensor provided on each of the forks in a straight line to face each other and configured to detect and guide an entry position of the end effector in a Y-direction and a Z-direction such that the detection pin is positioned at a center between the forks in plane and a set height;
a central hole portion penetrating through the base pad such that the detection pin is positioned therein when the forks move forward and the front end sensor detects the semicircular block; and
one or more central sensors provided on the base pad along an edge of the central hole portion to interact with the central hole portion in an inward direction and set a position of the end effector in an X-direction and a Z-direction such that the detection pin is set at the set position.

4. The automatic teaching apparatus according to claim 3, wherein, when the dummy port is positioned inside the specific load port, the dummy port is set at a fixed position with respect to the load port by a first positioner.

5. The automatic teaching apparatus according to claim 1, further comprising:
one or more stations provided along an edge of another side of the EFEM to be connected to the inside of the EFEM; and
a station teaching unit configured to detect a fixed position of the end effector in a state of unloading the wafer such that the wafer is placed in the fixed position within the station.

6. A transfer apparatus including a teaching system for teaching a delivery position of a wafer in a wafer carrier disposed on a load port installed in the transfer apparatus that forms a clean space, the transfer apparatus comprising:
a robot including a hand configured to hold a wafer, an arm configured to move the hand in a horizontal direction and a vertical direction, and a sensor provided on the hand,
a robot control device configured to perform at least detection of the sensor, and movement control of the arm and the hand, and
a teaching jig disposed on the load port and configured to maintain the clean space of the transfer apparatus in the same position as a delivery position of a wafer in the wafer carrier by the robot,
wherein the teaching jig has a specific feature disposed to determine a relative positional relationship with the delivery position of the wafer in the wafer carrier, and
wherein the robot control device operates the hand to detect the specific feature of the teaching jig by the sensor and stores the delivery position of the wafer based on a detected position of the specific feature.

7. The transfer apparatus according to claim 6, wherein the teaching jig includes a housing having one surface provided with an opening and a remaining surface shaped to hold the teaching jig,
the specific feature is provided inside the housing, and
the robot is configured to access the specific feature through the opening of the teaching jig that maintains the clean space of the transfer apparatus.

8. The transfer apparatus according to claim 6, wherein the teaching jig is a wafer carrier configured to accommodate a wafer, and a plate-shaped substrate having the specific feature is mounted in a wafer mounting stage in the wafer carrier.

9. The transfer apparatus according to claim 7, wherein the specific feature is provided on a plate-shaped substrate positioned at a height identical to that of the wafer disposed in the wafer carrier.

10. The transfer apparatus according to claim 7, wherein the teaching jig further includes a cover covering the opening, the cover being opened and closed by the load port.

11. The transfer apparatus according to claim 7, wherein the specific feature includes a first specific feature and a second specific feature, the first specific feature and the second specific feature being disposed to determine a relative positional relationship with each other, the second specific feature being positioned closer to the opening than the first specific feature, and
wherein the robot control device operates the hand to detect the second specific feature by the sensor, detects the first specific feature by the sensor based on a detected position of the second specific feature, and acquires the delivery position of the wafer based on a position of the first specific feature.

12. The transfer apparatus according to claim 11, wherein the first specific feature and the second specific feature are disposed in an arrangement position according to an angle of an axial line of the hand with respect to the opening when viewed in plan view.

13. The transfer apparatus according to claim 12, wherein the teaching jig has a first arrangement position and a second arrangement position different from the first arrangement position, and
wherein the first specific feature and the second specific feature are disposed in the first arrangement position when the hand accesses from the opening while the angle of the axial line of the hand with respect to the opening maintains approximately a right angle, and are disposed in the second arrangement position when the hand accesses from the opening while the angle of the axial line with respect to the opening does not maintain approximately a right angle, as viewed in plan view.

14. The transfer apparatus according to claim 11, wherein the first specific feature is disposed in a position to be detected by the sensor while an angle of an axial line of the hand with respect to the opening maintains, after the second specific feature is detected by the sensor.

15. The transfer apparatus according to claim 11, wherein the second specific feature is disposed in a position where at least a gap between a side wall of the housing and the hand is secured when detected by the sensor.

16. The transfer apparatus according to claim 11, wherein a plurality of first specific features and second specific features are provided hierarchically in multiple stages within the teaching jig.

17. The transfer apparatus according to claim 13, wherein, in the second arrangement position, a surface where the first specific feature is positioned and a surface where the second specific feature is positioned are different.

18. The transfer apparatus according to claim 11, wherein the sensor includes a first sensor installed at a front end of the hand, and a second sensor provided at a base end of the hand and having an optical axis orthogonal to an optical axis of the first sensor,
wherein the first specific feature includes a first detection portion and a second detection portion, and
wherein after the first sensor detects the second specific feature, the robot control device moves the hand to a position where the first sensor detects the second detection portion and the second sensor detects the first detection portion.

19. The transfer apparatus according to claim 18, wherein the first detection portion and the second detection portion have a relative positional relationship such that the second sensor detects the first detection portion and at the same time, the first sensor detects the second detection portion.

20. The transfer apparatus according to claim 18, wherein the second sensor is provided to traverse an opening provided in the base end of the hand, and when the first sensor detects the second detection portion and the first detection portion enters the opening, the hand and the second specific feature are configured not to interfere with each other.

21. The transfer apparatus according to claim 20, wherein the second sensor includes an alpha sensor having an optical axis parallel to the optical axis of the first sensor and a beta sensor having an optical axis orthogonal to each of the optical axes of the alpha sensor and the first sensor, and
wherein the beta sensor is provided to traverse the opening.

22. The transfer apparatus according to claim 6, wherein the teaching jig is disposed on the load port by an overhead hoist transport (OHT) or an automated guided vehicle (AGV).

23. A teaching system for teaching a delivery position of a wafer in a wafer carrier disposed on a load port installed in a transfer apparatus that forms a clean space, the teaching system comprising:
a robot including a hand configured to hold a wafer, an arm configured to move the hand in a horizontal direction and a vertical direction, and a sensor provided on the hand,
a robot control device configured to perform at least detection of the sensor, and movement control of the arm and the hand, and
a teaching jig disposed on the load port and configured to maintain the clean space of the transfer apparatus in the same position as the delivery position of the wafer in the wafer carrier by the robot,
wherein the teaching jig has a specific feature disposed to determine a relative positional relationship with the delivery position of the wafer in the wafer carrier, and
wherein the robot control device operates the hand to detect the specific feature of the teaching jig by the sensor and stores the delivery position of the wafer based on a detected position of the specific feature.

24. A robot that performs delivery of a wafer to and from a wafer carrier disposed on a load port installed in a transfer apparatus that forms a clean space,
a hand configured to hold the wafer,
an arm configured to move the hand in a horizontal direction and a vertical direction; and
a sensor provided on the hand,
wherein the robot detects a teaching jig for teaching a delivery position of the wafer in the wafer carrier by the sensor, thereby teaching the delivery position of the wafer,
wherein the teaching jig is disposed in the load port, configured to maintain the clean space of the transfer apparatus in the same position as the delivery position of the wafer in the wafer carrier by the robot, and has a specific feature disposed to determine a relative positional relationship with the delivery position of the wafer in the wafer carrier, and
wherein the robot operates the hand to detect the specific feature of the teaching jig by the sensor, and teaches the delivery position of the wafer based on a detected position of the specific feature.
